(19) United States
(12) Patent Application Publication
(10) Pub. No.: US 2013/0178063 A1
(43) Pub. Date: Jul. 11, 2013

(54) METHOD OF MANUFACTURING SEMICONDUCTOR DEVICE HAVING SILICON THROUGH VIA

(71) Applicants: Chun-Ling Lin, Tainan City (TW); Chi-Mao Hsu, Tainan City (TW); Tsun-Min Cheng, Changhua County (TW); Jia-Jia Chen, Taichung City (TW); Chin-Fu Lin, Tainan City (TW)

(72) Inventors: Chun-Ling Lin, Tainan City (TW); Chi-Mao Hsu, Tainan City (TW); Tsun-Min Cheng, Changhua County (TW); Jia-Jia Chen, Taichung City (TW); Chin-Fu Lin, Tainan City (TW)

(73) Assignee: UNITED MICROELECTRONICS CORP., HSINCHU (TW)

(21) Appl. No.: 13/347,758

(22) Filed: Jan. 11, 2012

(51) Int. Cl. H01L 21/28

(52) U.S. Cl. 438/675; 257/E21.158

(57) ABSTRACT

A method of manufacturing semiconductor device having silicon through via is disclosed, and conductor can be fully filled in the silicon through via. First, a silicon substrate is provided. Then, the silicon substrate is etched to form a through silicon via (TSV), and the through silicon via extends down from a surface of the silicon substrate. Next, a barrier layer is formed on the silicon substrate and in the through silicon via. Then, a seed layer is formed on the barrier layer and in the through silicon via. Afterward, a wet treatment is performed on the seed layer over the silicon substrate and within the through silicon via. The through silicon via is then filled with a conductor.

### BACKGROUND OF THE INVENTION

1. Field of the Invention

The invention relates in general to a method of manufacturing semiconductor device, and more particularly the method of manufacturing semiconductor device having silicon through via structure fully filled with conductor.

2. Description of the Related Art

TSV (through silicon via) technology is developed for providing interconnection between stacked wafers (chips) in three-dimensional integrated circuit (3D-IC) design. Compared to the conventional stacked IC package, TSV creates a 3D vertical conducting path, and the length of conductive line is reduced to equal the thickness of wafers (chips) substantially, thereby increasing the density of stacked wafers (chips) and enhancing the speed of signal transfer and electrical transmission. Also, parasitic effect can be decreased due to the vertical connection of conductor, so as to lower power consumption. Moreover, TSV technology offers the heterogeneous integration of different ICs (for example; stacking memory on the processor) to achieve the multi-functional integration. TSV technology involves many important processes of via formation, via filling, wafer bonding, etc. Those processes can be classified as via-first approach and via-last approach according to the forming process in order and final configurations.

There are various processes using TSV technology for the three-dimensional integration. Those processes can be classified as via-first approach and via-last approach according to the forming process in order and final configurations. In the via-first approach, the steps of forming the through silicon vias and filling conductor in the vias is performed before fabrication of back end of the Line (BEOL), wherein the substrate may include any of active components or not. In the via-last approach, the steps of forming the through silicon vias and filling conductor in the vias is performed after fabrication of BEOL. Whether the process (ex: via-first approach or via-last approach) is adopted, the quality of through silicon via filled with conductor has considerable effect on the electrical performance of the stacked wafers (chips).

### SUMMARY OF THE INVENTION

The disclosure is directed to a method of manufacturing semiconductor device having silicon through via. The embodiment of the disclosure utilizes a pre-wetting step performed before filling conductor in the silicon through via of the silicon substrate, resulting conductor fully filling the silicon through via without generating air bubble in via. The silicon through via with full-filling conductor possesses good electrical properties, and thus enhances the reliability of the applied device such as 3D package.

According to an aspect of the present disclosure, a method of manufacturing semiconductor device having silicon through via is disclosed. First, a silicon substrate is provided. Then, the silicon substrate is etched to form a through silicon via (TSV), and the through silicon via extends down from a surface of the silicon substrate. Next, a barrier layer is formed on the silicon substrate and in the through silicon via. Then, a seed layer is formed on the barrier layer and in the through silicon via. Afterward, a wet treatment is performed on the seed layer over the silicon substrate and within the through silicon via. The through silicon via is then filled with a conductor.

The disclosure will become apparent from the following detailed description of the preferred but non-limiting embodiments. The following description is made with reference to the accompanying drawings.

### BRIEF DESCRIPTION OF THE DRAWINGS

FIG. 1 is a flowchart of a method of manufacturing semiconductor device having silicon through via according to the embodiment of the disclosure.

FIG. 2A-FIG. 2H illustrate a method of manufacturing semiconductor device having silicon through via according to the embodiment of the disclosure.

FIG. 3A-FIG. 3E illustrate the method of manufacturing semiconductor device having silicon through via of the embodiment of the disclosure applied in a via-first approach.

FIG. 4 illustrates a package containing several TSV wafers stacked vertically.

FIG. 5A-FIG. 5B illustrate the method of manufacturing semiconductor device having silicon through via of the embodiment applied in another via-first approach, wherein the through silicon vias are formed after formation of the active components.

FIG. 6A-FIG. 6B illustrate the method of manufacturing semiconductor device having silicon through via of the embodiment applied in a via-last approach, wherein the through silicon vias are formed after fabrication of BEOL.

### DETAILED DESCRIPTION OF THE INVENTION

According to the embodiment of the disclosure, a pre-wetting step is performed before filling conductor in the silicon through via of the silicon substrate, so that the silicon through via could be fully filled with conductor without air bubble formed in the silicon through via. The embodiment is described in details with reference to the accompanying drawings. The procedures and details of the formation method and the structure of the embodiment are for exemplification only, not for limiting the scope of protection of the disclosure. Moreover, secondary elements are omitted in the disclosure of the embodiment for highlighting the technical features of the disclosure. The identical elements of the embodiment are designated with the same reference numerals. Also, it is also important to point out that the illustrations may not be necessarily be drawn to scale, and that there may be other embodiments of the present disclosure which are not specifically illustrated. Thus, the specification and the drawings are to be regard as an illustrative sense rather than a restrictive sense.

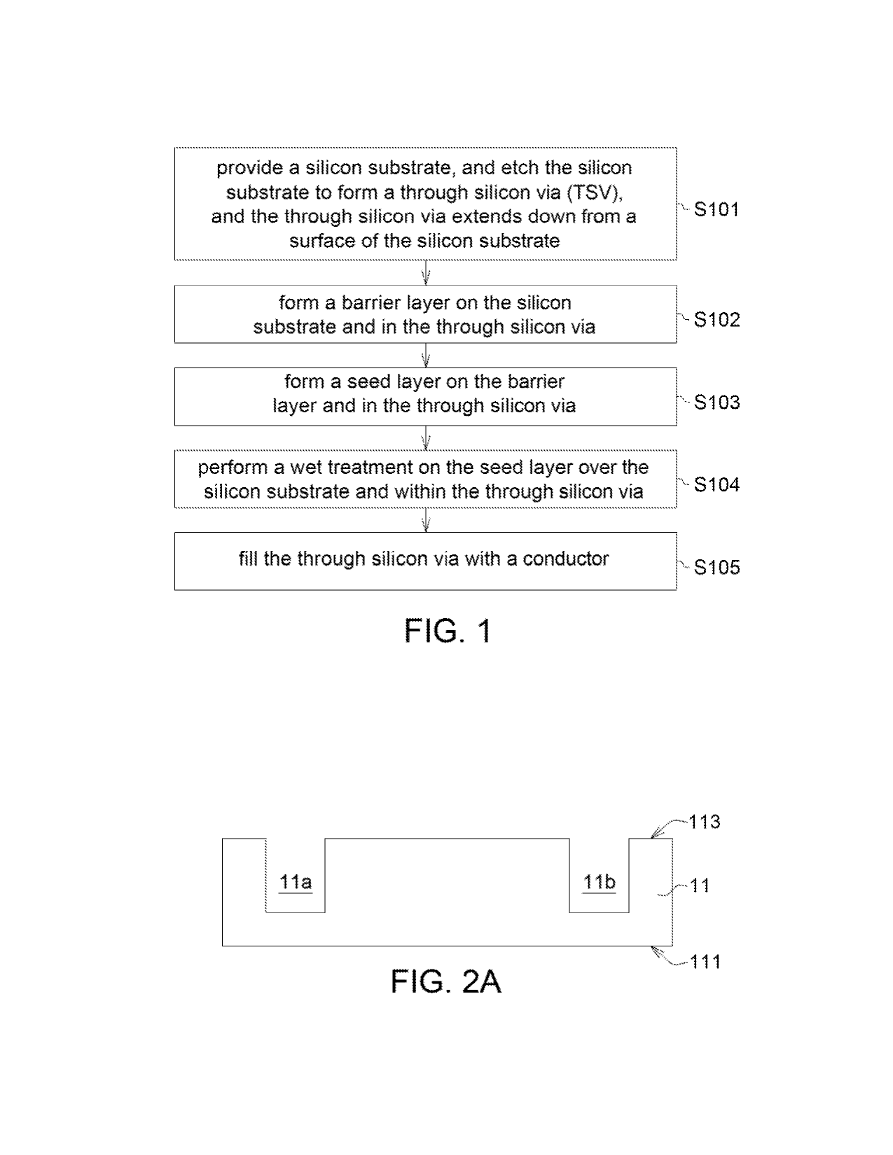

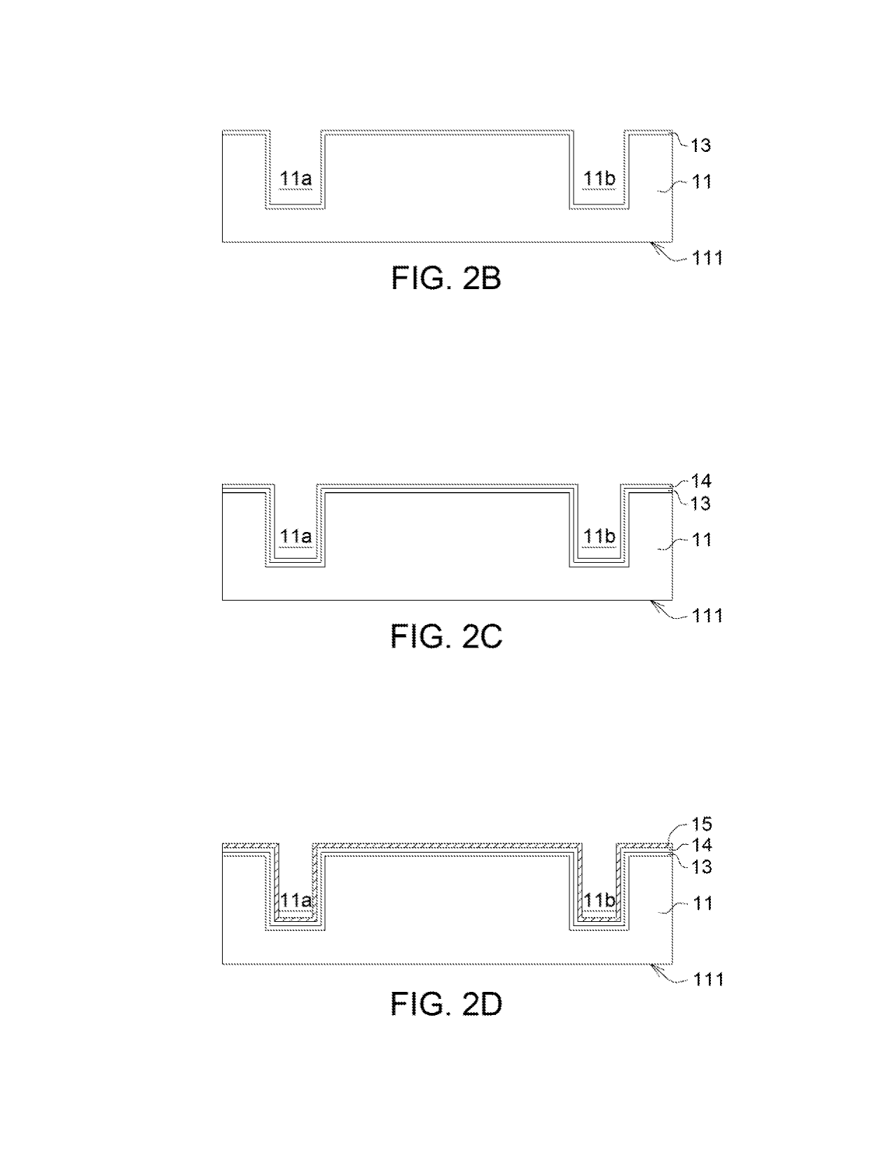

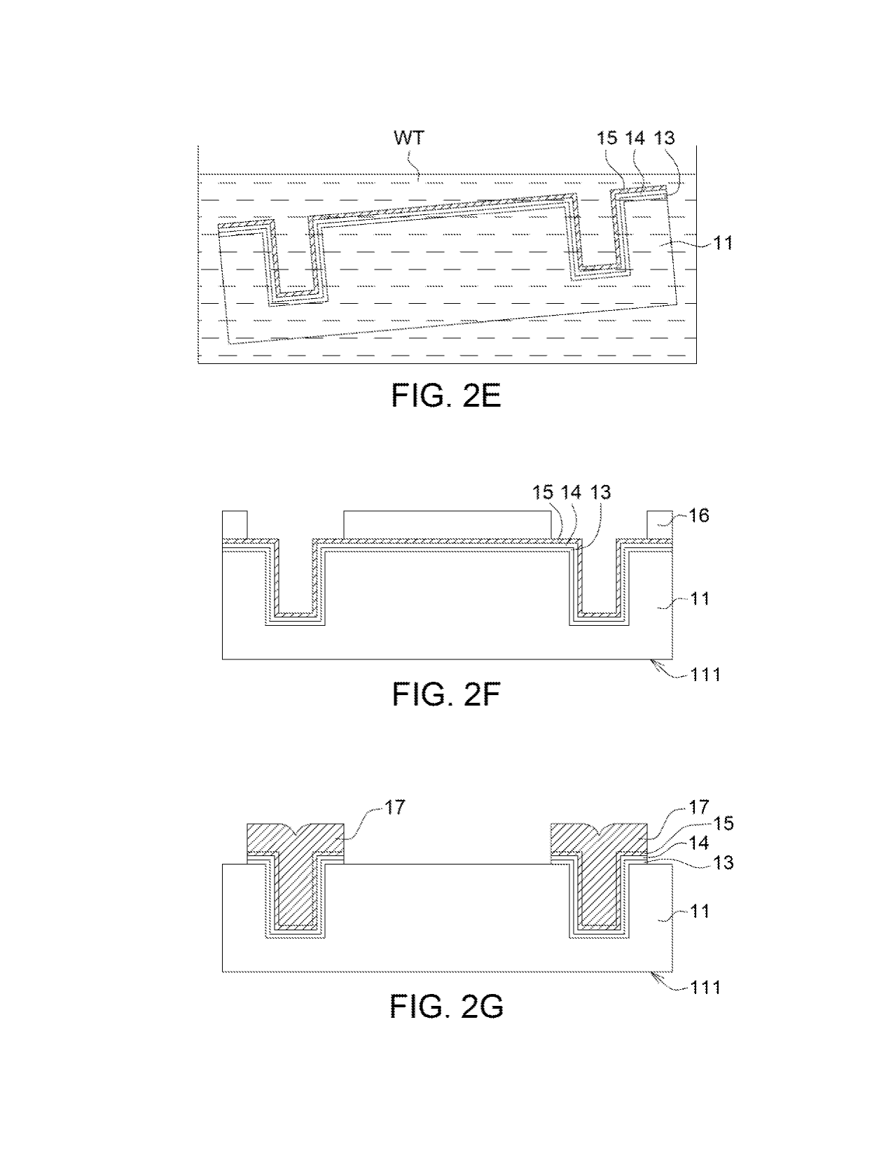

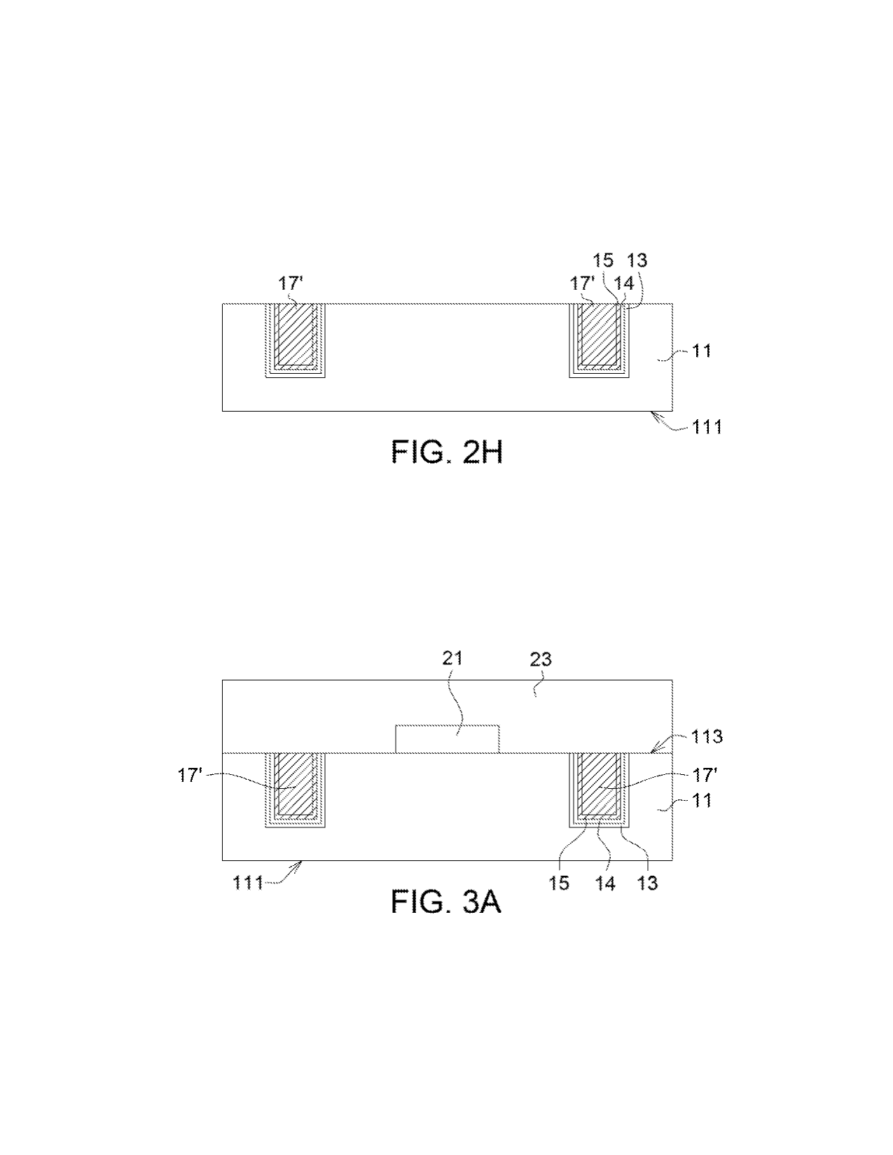

Please refer to FIG. 1 and FIG. 2A-FIG. 2H. FIG. 1 is a flowchart of a method of manufacturing semiconductor device having silicon through via according to the embodiment of the disclosure. FIG. 2A-FIG. 2H illustrate a method of manufacturing semiconductor device having silicon through via according to the embodiment of the disclosure. First, in step S101, a silicon substrate 11 is provided, and the silicon substrate 11 is etched to form a through silicon vias (TSV) 11a and 11b, as shown in FIG. 2A. In the embodiment, the silicon substrate 11 has a first surface 111 and a second surface 113, and the through silicon vias 11a and 11b as formed extend down from the second surface 113 of the silicon substrate 11.

In one embodiment, an aspect ratio of each of the through silicon vias 11a and 11b could be 6, approximately. In one embodiment, a through silicon via has a size of about 60 μm in depth and 10 μm in diameter (10 μm×60 μm). However, the dimensions of the through silicon vias 11a and 11b are not limited hereto, and could be modified in accordance with the actual needs of the practical applications.

As shown in FIG. 2B, a liner film 13 could be formed on the silicon substrate 11 and in the through silicon vias 11a and 11b as an isolation layer, for isolating the conductive TSV (formed in the subsequent procedure) from the substrate and active and passive components on the substrate. In one embodiment, formation of the liner film 13 could be deposition of an oxide layer, and a thickness of the liner film 13 could be 2000 Å.

In step S102, a barrier layer 14 is formed on the silicon substrate 11 and in the through silicon vias 11a and 11b, such as formed on the liner film 13, as shown in FIG. 2C. The barrier layer 14 could be a stack layer of suitable materials. For example, if copper is used as the conductor material subsequently, a Ta/TaN stack layer could be applied as the barrier layer 14 for preventing copper diffusion. In one embodiment, a thickness of the Ta/TaN stack layer is 1.1K, approximately.

Next, in step S103, a seed layer 15 is formed on the barrier layer 14 and in the through silicon vias 11a and 11b, as shown in FIG. 2D. Material of the seed layer 15 depends on material of the conductor filled in the through silicon vias 11a and 11b. For example, if copper is used as the conductor material subsequently, the seed layer 15 includes copper. In one embodiment, a thickness of the seed layer 15 is 15K, approximately.

Afterward, in step S104, a wet treatment is performed on the seed layer 15 over the silicon substrate 11 and in the through silicon vias 11a and 11b. In one embodiment, the silicon substrate 11 could be immersed in a treating agent WT, as shown in FIG. 2E; however, the invention is not limited thereto. Examples of the treating agent WT include deionized water (DI) and a chemical solution, and the immersing time could be about 30 to 40 seconds. In one embodiment, the chemical solution may comprise sulfuric acid, copper sulfate and polymer. It is, of course, understood that this composition is one of applicable chemical solutions, and is not a limitation for the disclosure. Also, it is known for people skill in this field that the way for conducting the wet treatment is not limited to immersion, and the treating time (such as immersing time) could adjusted depending on the components, concentrations and treating methods of the treating agent. The disclosures of the embodiments are not intended to limit the invention.

Next, in step S105, the through silicon vias 11a and 11b is filled with a conductor. One of applicable methods is provided below for illustration. However, it is understood that the method illustrated below is not intended to limit the invention. The modifications and variations can be made without departing from the spirit of the disclosure to meet the requirements of the practical applications.

As shown in FIG. 2F, a patterned photo-resist (PR) 16 is formed on the seed layer 15, to define the conductive pattern subsequently. Next, a conductive layer 17 is plated on the seed layer 15 and fully filling the through silicon vias 11a and 11b. Then, the patterned PR and the seed layer 15, the barrier layer 14 and the liner film 13 outside the conductive pattern region (ex. parts uncovered by the conductive layer 17) are removed, as shown in FIG. 2G. Afterward, a chemical mechanical polish (CMP) is performed on the conductive layer 17 to remove the excess conductive layer 17, the seed layer 15 and the barrier layer q4 and the liner film 13 (ex, above the surface of the silicon substrate 11), so that the through silicon vias 11a and 11b are fully filled with the conductor 17′ after polishing, as shown in FIG. 2H.

In another embodiment, a conductive layer, of course, could be directly plated on the seed layer 15 to fully fill the through silicon vias 11a and 11b, and the conductive layer is chemically mechanically polished to obtain the structure as shown in FIG. 2H.

The method of the embodiment as depicted in FIG. 2A-FIG. 2H could be applied to different TSV processes, such as the via-first approach and the via-last approach.

When the method of the embodiment is applied to the via-first approach, steps of forming the through silicon vias and filling conductor in the vias could be performed before formation of the active components such as complementary metal-oxide-semiconductor (CMOS) and others, as shown in FIG. 2H. Then, the active components and subsequent processes are fabricated.

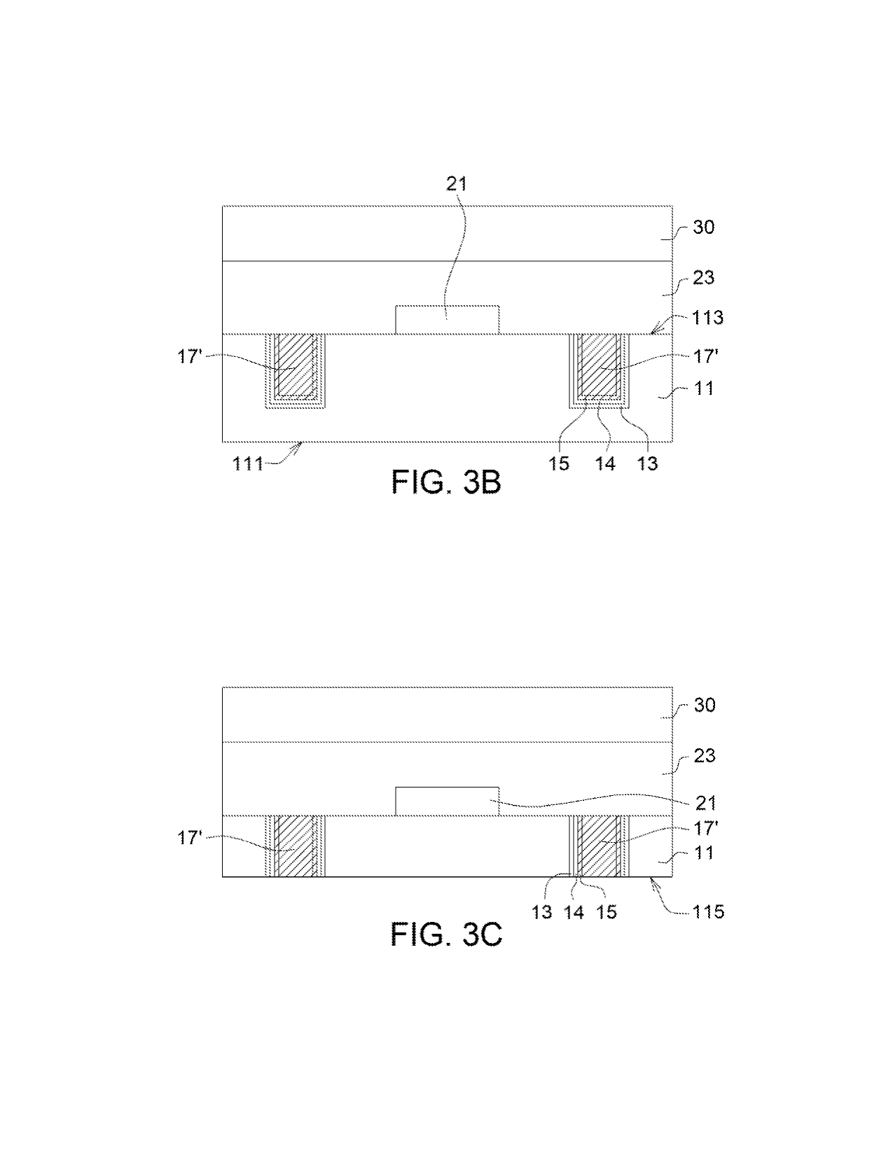

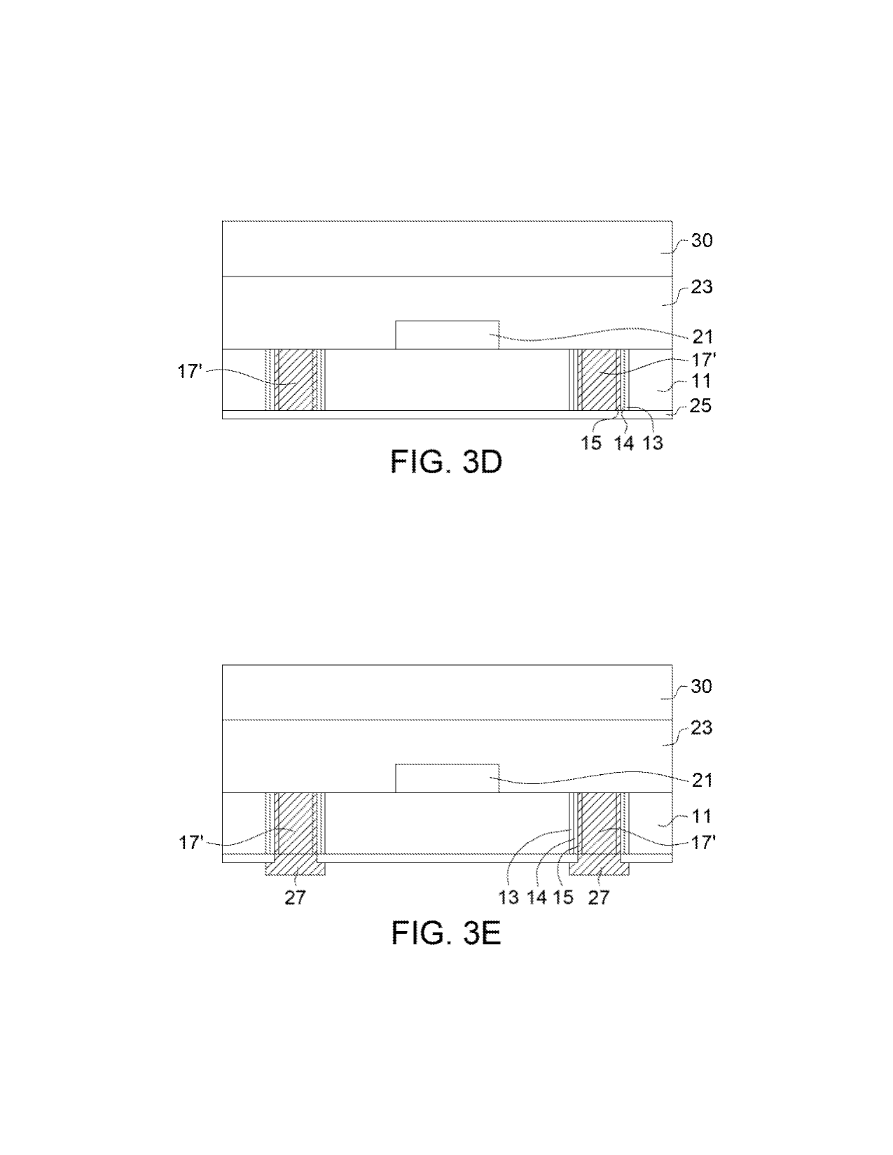

FIG. 3A-FIG. 3E illustrate the method of manufacturing semiconductor device having silicon through via of the embodiment of the disclosure applied in a via-first approach. As shown in FIG. 3A, an active component such as CMOS 21 is formed on the second surface 113 of the silicon substrate 11 of the structure depicted in FIG. 2H. Afterward, fabrication of back end of the Line (BEOL) 23 is completed.

Next, a carrier 30 is disposed at one side of the BEOL 23, as shown in FIG. 3B. Then, a thinning process is performed on the first surface 111 of the silicon substrate 11 by CMP, grinding, or a combination thereof, as shown in FIG. 3C. The surface 115 of the thinned silicon substrate 11 exposes the conductors 17′ filled in the through silicon vias 11a and 11b.

After thinning step, an insulating layer 25 could be formed on the surface 115 of the silicon substrate 11, as shown in FIG. 3D, to prevent the silicon contamination when two or more substrates (chips) are stacked vertically in a 3D package. For example, an oxide layer could be formed on the surface 115 by plasma enhanced chemical vapor deposition (PECVD) as the insulating layer 25

As shown in FIG. 3E, the insulating layer 25 is then patterned to exposes the conductors 17′ filled in the through silicon vias 11a and 11b, and the conductive pads 27 such as copper pads are formed at positions corresponding to the through silicon vias 11a and 11b, to be the contacts for the stacked substrates (chips) of a 3D package. When the substrates (chips) are vertically stacked, the carrier 30 could be removed after dicing step.

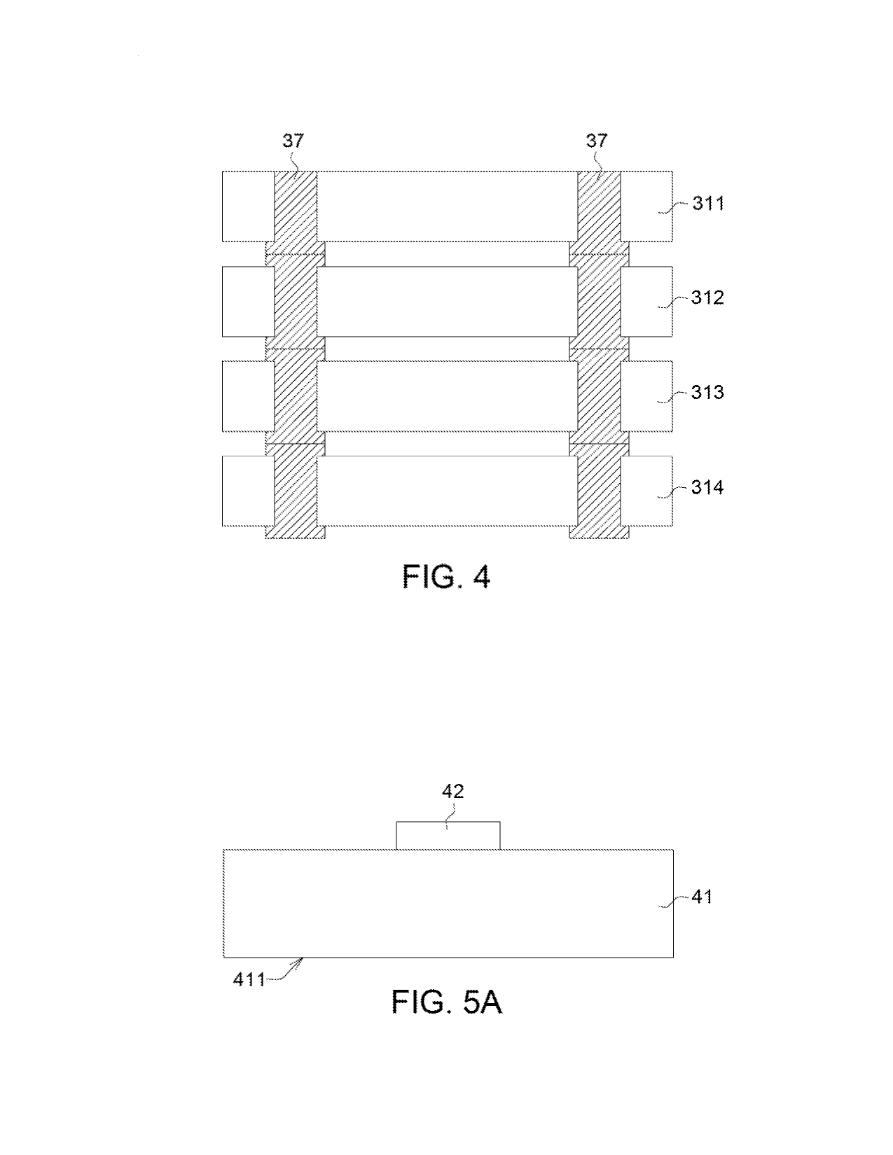

A 3D package contains two or more wafers (chips) having TSVs which fabricated according to by method of the embodiment. As shown in FIG. 4, after the wafers 311-314 are vertically stacked, the connection of the TSVs of each wafer forms the conductors 37 and creates a conducting path to replace edge wiring, thereby reducing the length of conductive line to the thickness of wafers (chips). The vertical connections through the body of the wafers (chips) in 3D packages not only enhance the speed of signal transfer and electrical transmission, but also perform the heterogeneous integration of different ICs; for example, stacking memory on the processor.

In the via-first approach, besides the through silicon vias and filling conductor in the vias are performed before formation of the active components (ex: CMOS) as described above, the method of the embodiment could be further applied after formation of the active components and before fabrication of BEOL. Meanwhile, the provided silicon substrate may comprise a plurality of active components and contacts before forming the through silicon via.

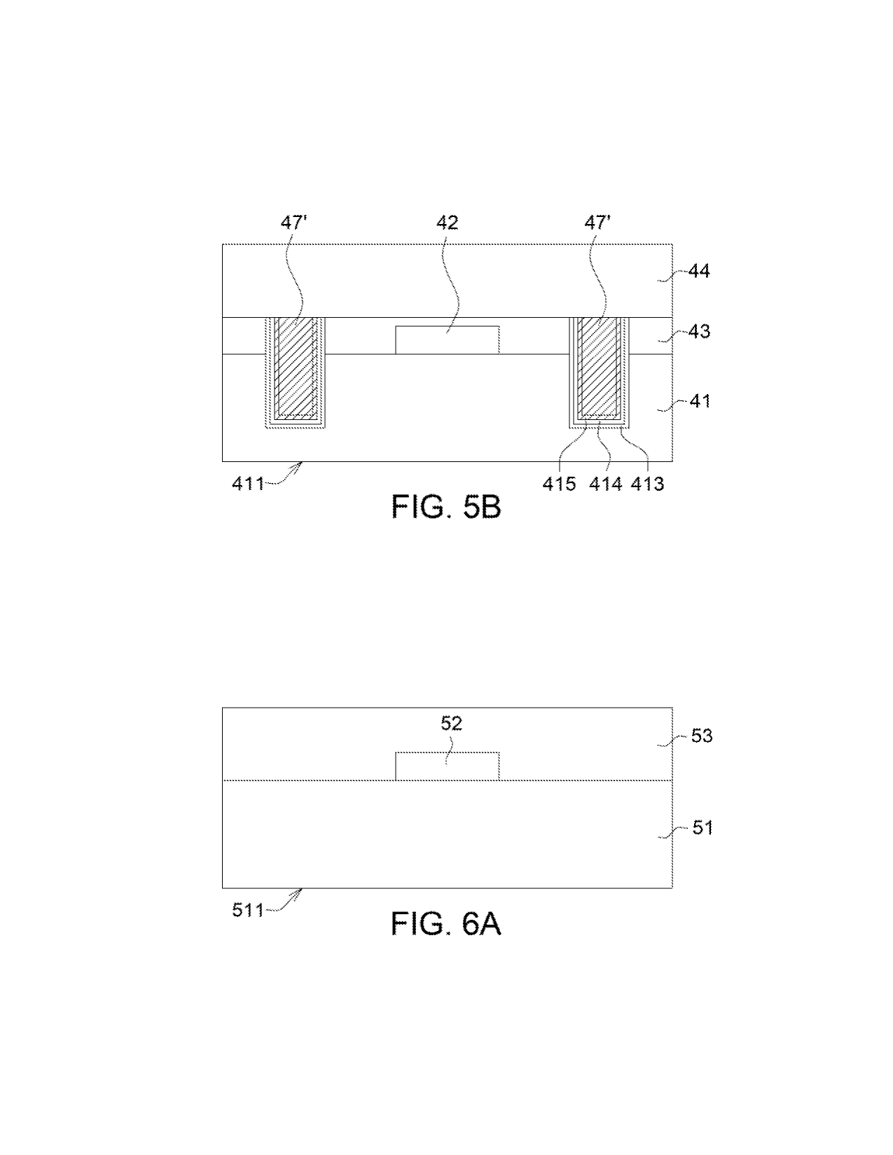

Please refer to FIG. 2A-FIG. 2H and FIG. 5A-FIG. 5B. FIG. 5A-FIG. 5B illustrate the method of manufacturing semiconductor device having silicon through via of the embodiment applied in another via-first approach, wherein the through silicon vias are formed after formation of the active components. As shown in FIG. 5A, a CMOS 42 is formed on the silicon substrate 41, firstly. Then, an inter-layer dielectric (ILD) 43 is formed on the silicon substrate 41 to cover the CMOS 42. Next, the silicon through vias filled with conductor 47′ are formed in the silicon substrate 41 by the steps as the processes depicted in FIG. 2A-FIG. 2H. Similarly, a wet treatment is performed on the seed layer 415 over the silicon substrate 41 and in the through silicon vias before filling the conductors 47′. Afterward, fabrication of back end of the Line (BEOL) 44 on the ILD 43 is completed in the subsequent procedures, as shown in FIG. 5B. Other components in FIG. 5B are already disclosed above as depicted in FIG. 2A-FIG. 2H, and are not redundantly described here.

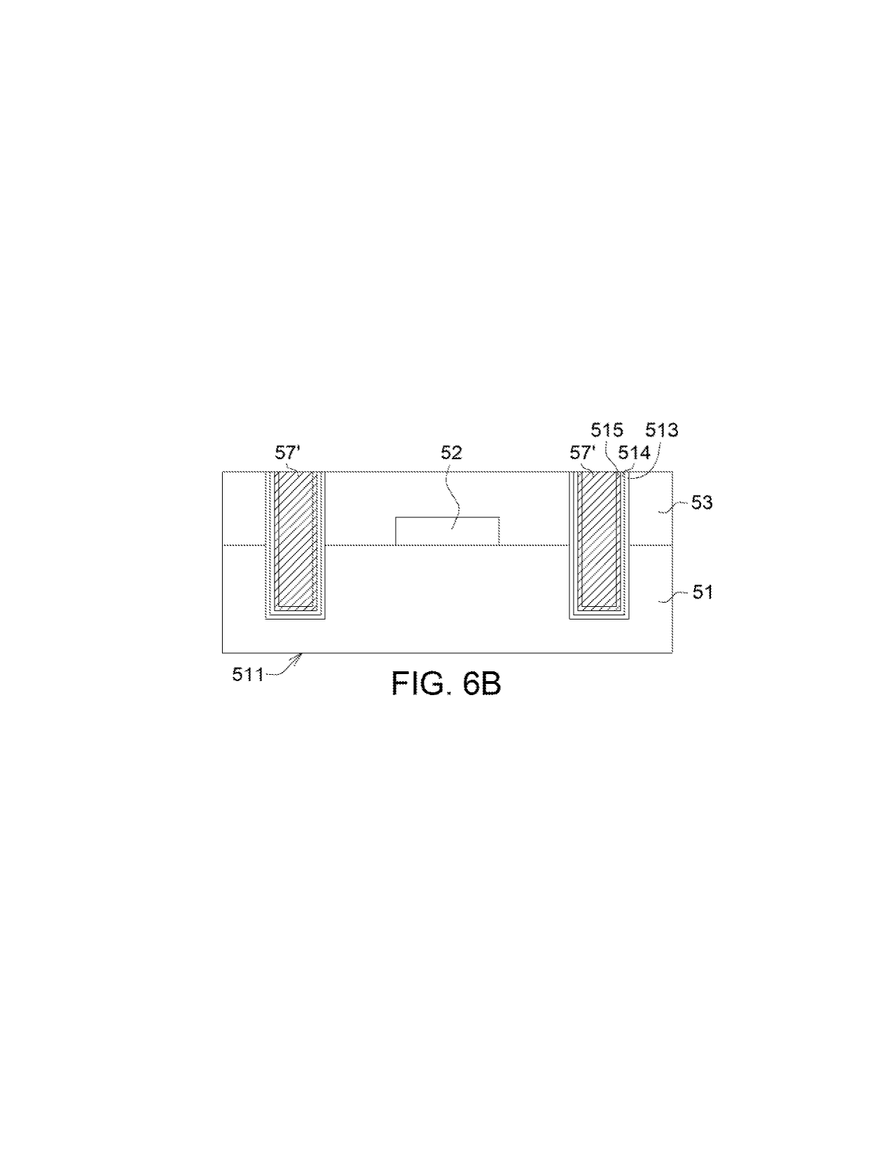

Additionally, besides the via-first approach, the method of the embodiment as depicted in FIG. 2A-FIG. 2H could be applied to the via-last approach. In the via-last approach, the steps of forming the through silicon vias and filling conductor in the vias could be performed after fabrication of BEOL, and before or after stacking the wafers. Meanwhile, the provided silicon substrate may comprise a plurality of active components and interconnects of BEOL before forming the through silicon via. Please refer to FIG. 2A-FIG. 2H and FIG. 6A-FIG. 6B. FIG. 6A-FIG. 6B illustrate the method of manufacturing semiconductor device having silicon through via of the embodiment applied in a via-last approach, wherein the through silicon vias are formed after fabrication of BEOL. As shown in FIG. 6A, a CMOS 52 is formed on the silicon substrate 51, and the BEOL 53 is completed in the subsequent procedures. Then, as shown in FIG. 6B, the silicon through vias filled with conductor 57′ are formed in the silicon substrate 51 by the steps depicted in FIG. 2A-FIG. 2H. Similarly, a wet treatment is performed on the seed layer 515 over the silicon substrate 51 and in the through silicon vias before filling the conductors 57′. Other components in FIG. 6B are already disclosed above as depicted in FIG. 2A-FIG. 2H, and are not redundantly described here.

Several experiments are conducted to investigate the effect of wet treatment on the conductors filled in the through silicon vias. The experimental results have indicated that air bubbles are generated in the bottoms of the vias (almost occupying ½ space of via, observed by electron microscope) after conductors filled in the through silicon vias, if no wet treatment is conducted before filling the conductors in the through silicon vias. Electrical performance of the wafer would be deteriorated due to the occurrences of air bubbles. In contrast, the conductors are well filled in the through silicon vias if the wet treatment is performed on the silicon substrate (including the through silicon vias) before filling the conductors in the through silicon vias.

In some of experiments, DI water is used for performing the wet treatment, and the silicon substrate is immersed in DI water, and the conductor is then filled in the through silicon vias. The experimental results are described below.

(1) The through silicon via in the silicon substrate, positioned close to the center of the substrate, has a depth of about 32.7 μm. When the conductor is filled to the half depth of the through silicon via, no air bubble is generated in the bottoms of the via, and the middle opening of the through silicon via is about 4.3 μm, and the top opening of the through silicon via is about 5.9 μm. Also, the top opening of the through silicon via is not sealed.

(2) The through silicon via in the silicon substrate, positioned close to the edge of the substrate, has a depth of about 29.3 μm. When the conductor is filled to the half depth of the through silicon via, no air bubble is generated in the bottoms of the via, and the middle opening of the through silicon via is about 3.0 μm, and the top opening of the through silicon via is about 6.0 μm. Also, the top opening of the through silicon via is not sealed.

Furthermore, in some of experiments, a chemical solution (containing sulfuric acid, copper sulfate and polymer) is used for performing the wet treatment, and the silicon substrate is immersed in the chemical solution, and the conductor is then filled in the through silicon vias. The experimental results are described below.

(3) The through silicon via in the silicon substrate, positioned close to the center of the substrate, has a depth of about 30.8 μm. When the conductor is filled to the half depth of the through silicon via, no air bubble is generated in the bottoms of the via, and the middle opening of the through silicon via is about 7.0 μm, and the top opening of the through silicon via is about 7.3 μm. Also, the top opening of the through silicon via is not sealed.

(4) The through silicon via in the silicon substrate, positioned close to the edge of the substrate, has a depth of about 29.7 μm. When the conductor is filled to the half depth of the through silicon via, no air bubble is generated in the bottoms of the via, and the middle opening of the through silicon via is about 7.9 μm, and the top opening of the through silicon via is about 7.4 μm. Also, the top opening of the through silicon via is not sealed.

According to the aforementioned methods of the embodiments, the silicon through via of the silicon substrate is pre-wetted by the wet treatment, and the conductor is fully filled in the silicon through via without generation of air bubble, thereby enhancing the electrical performance and reliability of the device in application. The method of the embodiment could be applied to different TSV processes, including the via-first approach and the via-last approach. The conductor can be well filled in the silicon through via as long as a pre-wetting step performed before filling conductor. Moreover, the flexibility of the embodiment in application is large. In practical applications, the steps of the methods could be adjusted or modified according to actual needs. For example, the components of the treating agent such as chemical solution could be chosen, and the treating way and time for the substrate could be adjusted according to practical conditions. Additionally, the method of the embodiment could be incorporated in current processes. Effect of well-filled conductor could be easy and fast to achieve in cost-controlled circumstance. Thus, the method of the embodiment has significant contribution to 3D IC designed techniques, particular to 3D package in the trend of size reduction.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A method of manufacturing semiconductor device having silicon through via, comprising:
providing a silicon substrate;
etching the silicon substrate to form a through silicon via (TSV), and the through silicon via extending down from a surface of the silicon substrate;
forming a barrier layer on the silicon substrate and in the through silicon via;
forming a seed layer on the barrier layer and in the through silicon via;
performing a wet treatment on the seed layer over the silicon substrate and within the through silicon via by using a chemical solution comprising sulfuric acid, copper sulfate and polymer; and
filling the through silicon via with a conductor.

2. The method of manufacturing semiconductor device having TSV according to claim 1, wherein an aspect ratio of the through silicon via is about 6.

3. The method of manufacturing semiconductor device having TSV according to claim 1, wherein the through silicon via has a size of about 60 μm in depth and 10 μm in diameter.

4. The method of manufacturing semiconductor device having TSV according to claim 1, further comprising forming a liner film on the silicon substrate and in the through silicon via after forming the through silicon via.

5. The method of manufacturing semiconductor device having TSV according to claim 4, wherein the liner film is an oxide layer.

6. The method of manufacturing semiconductor device having TSV according to claim 1, wherein the barrier layer is a stack layer of Ta and TaN.

7. The method of manufacturing semiconductor device having TSV according to claim 1, wherein the seed layer and the conductor comprise copper.

8-10. (canceled)

11. The method of manufacturing semiconductor device having TSV according to claim 1, wherein the silicon substrate is immersed in a treating agent comprising the chemical solution to performing the wet treatment on the seed layer over the silicon substrate and within the through silicon via.

12. The method of manufacturing semiconductor device having TSV according to claim 11, wherein the silicon substrate is immersed in the treating agent for about 30 to 40 seconds.

13. The method of manufacturing semiconductor device having TSV according to claim 1, wherein after performing the wet treatment step, the method further comprises:
plating a conductive layer on the seed layer and fully filling the through silicon via; and
performing a chemical mechanical polish (CMP) on the conductive layer to remove the excess conductive layer, the seed layer and the barrier layer, so that the through silicon via filled with the conductor after polishing.

14. The method of manufacturing semiconductor device having TSV according to claim 1, wherein the provided silicon substrate comprises a plurality of active components before forming the through silicon via.

15. The method of manufacturing semiconductor device having TSV according to claim 14, wherein the provided silicon substrate further comprises a plurality of contacts before forming the through silicon via.

16. The method of manufacturing semiconductor device having TSV according to claim 14, wherein the provided silicon substrate further comprises a plurality of interconnects before forming the through silicon via.
